(19) United States
(12) Patent Application Publication
(10) Pub. No.: US 2026/0278184 A1
(43) Pub. Date: Sep. 17, 2026

(54) Auto Dimensioning Tool for Construction Mobile Applications

(71) Applicant: Autodesk, Inc., San Francisco, CA (US)

(72) Inventors: Haik H. Lorenz, Langenzersdorf (AT); Preston E. Garno, Sterling Heights, MI (US); Manjiri McCoy, Lake Oswego, OR (US)

(73) Assignee: Autodesk, Inc., San Francisco, CA (US)

(21) Appl. No.: 19/079,269

(22) Filed: Mar. 13, 2025

(51) Int. Cl. G06F 30/12

(52) U.S. Cl. CPC G06F 30/12

(57) ABSTRACT

A method and apparatus for automatically presenting a dimension of a depiction of an object is disclosed. One embodiment is evidenced by a method which comprises accepting a hit point on the depiction of the object and automatically presenting the dimension according to the plurality of surface boundary edges. The surface of the depicted object may be determined by collecting a plurality of connected triangles and edges that form the surface, then for each connected triangle, determining the triangle edges that form the border of the surface, and the triangle border vertices, and finally collating the triangle edges to produce the plurality of surface boundary edges from the triangle border edges.

### BACKGROUND

### 1. Field

The present disclosure relates to systems and methods for computer modeling of objects using processing devices and in particular, for a method, apparatus, and system to automatically generate dimension lines of such depicted objects.

### 2. Description of the Related Art

The use of graphics programs such as Computer Aided Design (CAD) application programs is well known in the art. CAD drawings often have many components (referred to as objects or graphics objects) that together define the drawing. In such CAD drawings, it is useful to provide the user with a means to automatically determine and display the dimensions of such objects. With many such models, object dimensions may be obtained by picking end points on the model itself. For example, the model may require the user to pick a point (with a longpress-drag gesture for snapping to vertices, midpoints etc.), then repeat the process to pick a second point, and get the measure between the two points.

This may be difficult in some use cases, particularly field use implemented by small mobile devices. For example, construction workers often wear gloves, work on phones, and such precise gestures are difficult to accomplish.

What is needed is a simple tool that allows the user to automatically present a dimension of a surface of an object with a single tap, while avoiding presenting dimensions that are uninteresting or repetitive.

### SUMMARY

To address the requirements described above, this document discloses a system and method for producing quick dimensions for surfaces with a single tap selection. In one embodiment, the method computes connected triangles and edges, then automatically computes dimensions based upon the hit position and surface geometry. Two modes are presented. In a first mode, Internal dimensions lines are computed by determining a straight line passing through the hit point and perpendicularly intersecting the boundary of the object as well as a boundary on an opposite side of the object. This process is iterated through other candidate interior dimension lines to identify other interior dimension lines and to eliminate duplicates. Once identified, the dimension lines, along with the dimensions of those lines, are presented to the user. The number of presented interior dimension lines may be limited to prevent a confusing display of lines. In a second mode, the computed triangles and edges are used to find dimensions of boundary edges of the object.

The features, functions, and advantages that have been discussed can be achieved independently in various embodiments of the present invention or may be combined in yet other embodiments, further details of which can be seen with reference to the following description and drawings.

### BRIEF DESCRIPTION OF THE DRAWINGS

Referring now to the drawings in which like reference numbers represent corresponding parts throughout:

FIGS. 1A-1B are diagrams illustrating an embodiment of a technique of automatically presenting dimensions of a depiction of an object;

FIG. 1C is a diagram illustrating an embodiment of an exemplary technique for collating the triangle edges to produce the plurality of surface boundary edges from the border edges of the peripheral triangles;

FIG. 2 is a diagram illustrating one embodiment of a depiction of an object;

FIGS. 3A-3C illustrate exemplary embodiments of triangle edge collation;

FIGS. 4A-4C are diagrams depicting exemplary operations that can be performed to present the dimension of a depicted object;

FIGS. 5A-5C are diagrams depicting embodiments of the display of dimension lines and associated dimensions;

FIGS. 6A-6C are diagrams that further illustrate how judicious selection of the hit point allows the user to obtain dimension lines and dimensions associated with different boundary lines;

FIGS. 7A-7C illustrate the depictions of dimension lines and associated dimensions used on curved surfaces, presented after selection of hit points;

FIGS. 8A and 8B illustrate a particular use case wherein the object is circular and hit point results in dimension lines;

FIGS. 9A and 9B illustrate a use case where the depicted object is a high order polygon with several edges;

FIG. 10A is a diagram illustrating an exemplary result of using the exterior dimension mode to determine the dimensions of a wall, using boundary edges;

FIG. 10B is a diagram illustrating one embodiment of how a line showing the diameter of the circle and the length of that diameter may be presented;

FIGS. 11A-11D are diagrams illustrating one embodiment of the result of edge-dimensioning higher order polygons as described in FIG. 4C;

FIG. 12 is a diagram illustrating an exemplary computer system that could be used to implement processing elements of the measurement system; and

FIG. 13 is a diagram illustrating a typical distributed/cloud-based computer system using a network to connect client computers to server computers.

### DESCRIPTION

In the following description, reference is made to the accompanying drawings which form a part hereof, and which is shown, by way of illustration, several embodiments. It is understood that other embodiments may be utilized and structural changes may be made without departing from the scope of the present disclosure.

### Overview

When using a mobile viewer application on a construction site, the user is typically less familiar with computer implemented construction models. At the same time, it is important that they have very simple tools for measuring dimensions.

Many mobile viewer applications (such as Native Mobile Viewer 3D) utilize files that are meshes without the benefit of a full CAD data model, and are composed mainly of elements having triangle geometry. Because there is no BREP (boundary representation) data available, existing tools require the user to pick points on the model to measure between. In the field, this is a difficult tool for a construction worker to use. They often wear gloves, work on phones, and such precise gestures are difficult.

Described below is a system and method implementing a tool that allows the user, with a single tap on a surface, to get intelligent dimension information from that surface and provide relevant dimensions. The tool analyzes the surface geometry independent of the surface orientation in the world, and produces meaningful dimensions in most cases. The usefulness of this tool is applicable to any viewing application that does not have the benefit of full CAD data, but has broader applications as well. For example, the tool offers automatic dimension and edge measurements for items such as (1) the length and breadth of a wall; (2) the diameter of a circle; and (2) the thickness of a wall.

### Discussion

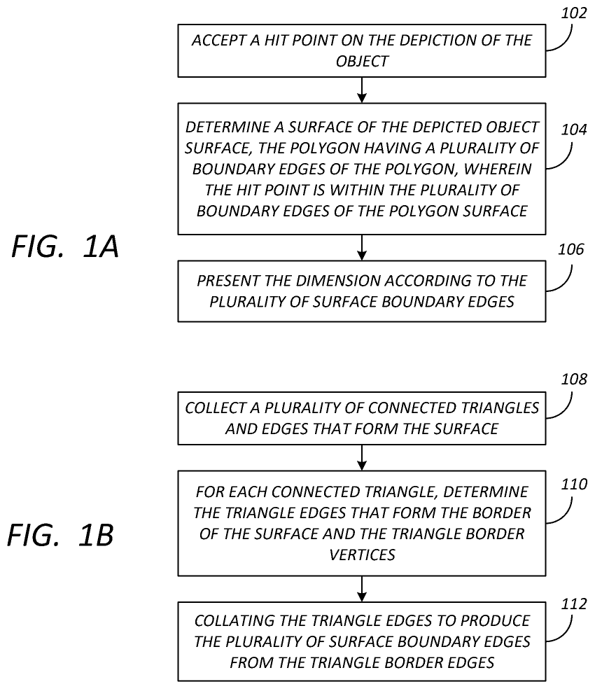

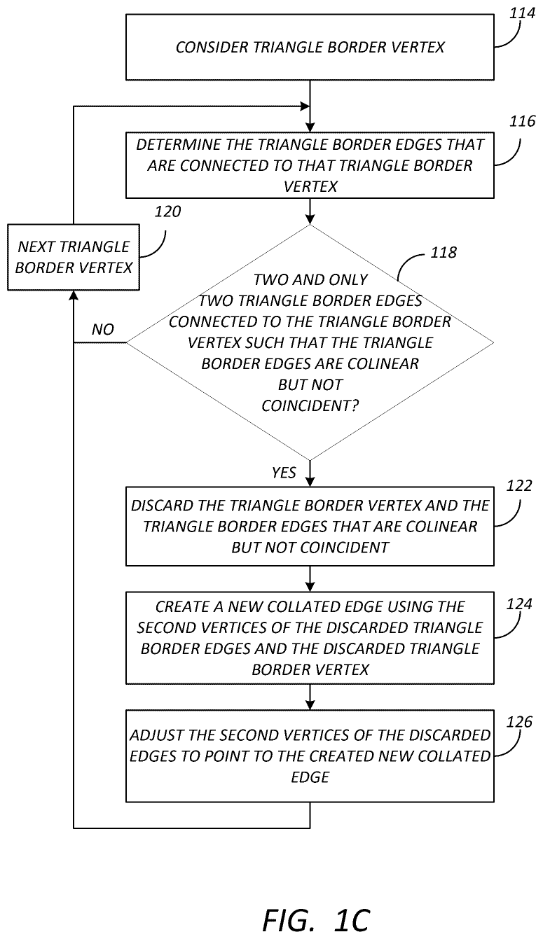

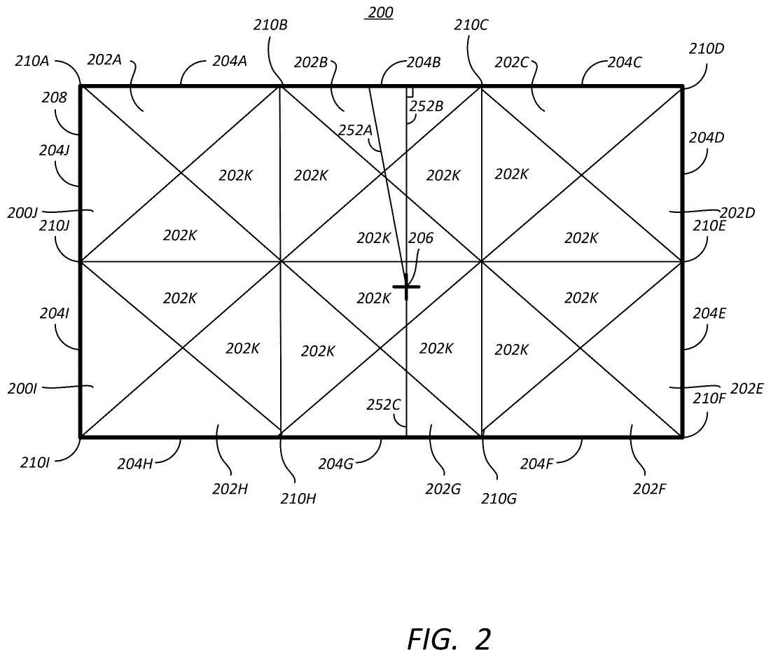

FIGS. 1A-1B are diagrams illustrating an embodiment of a technique of automatically presenting dimensions of a depiction of an object. FIGS. 1A-1B will be described in conjunction with FIG. 2 which is a diagram illustrating one embodiment of a depiction of an object surface.

Referring first to FIG. 1A, block 102 depicts accepting a hit point 206 on a depiction 200 of an object surface. This occurs, for example, when the user is presented with the depiction 200 of the object surface and using a cursor or mouse, or finger touch on the screen presenting the depiction 200 of the object surface, touches the indicated location on the depiction 200.

In block 104, a polygonal surface 208 (depicted by the heavy line in FIG. 2) approximating or defining the depicted object surface is determined. The polygon 208 has a plurality of boundary edges 204A-204J and the boundary edges 204A-204J surround the hit point 206 (e.g., the hit point 206 is within the plurality of boundary edges of the surface 208. An object surface need not be a polygon; this will be a polygon if the surface is flat, but not if it is curved, for example the curved surface of a cylinder. Curved surfaces, though not illustrated by the surface 200 which is a polygon, are included in the definition of “object surface” or “surface”.

FIG. 1B is a diagram illustrating an embodiment of an exemplary technique for determining the surface 208 of the depicted object. In block 108, a plurality of connected triangles 202A-202K and edges that form the surface 208 are collected. The triangles 202A-202K include peripheral triangles 202A-202J (e.g., triangles having an edge forming at least part of the border of the surface 208) and interior triangles (e.g., triangles not having an edge that forms at least part of the border of the surface 208) 202K. In block 110, for each connected triangle 202A-202K, triangle edges 204A-204J that form the border of the surface 208 are determined, as well as the vertices 210A of those triangle edges 204A-204J. In block 112, the triangle edges are collated to produce a plurality of boundary edges (triangle border edges 204A-204J).

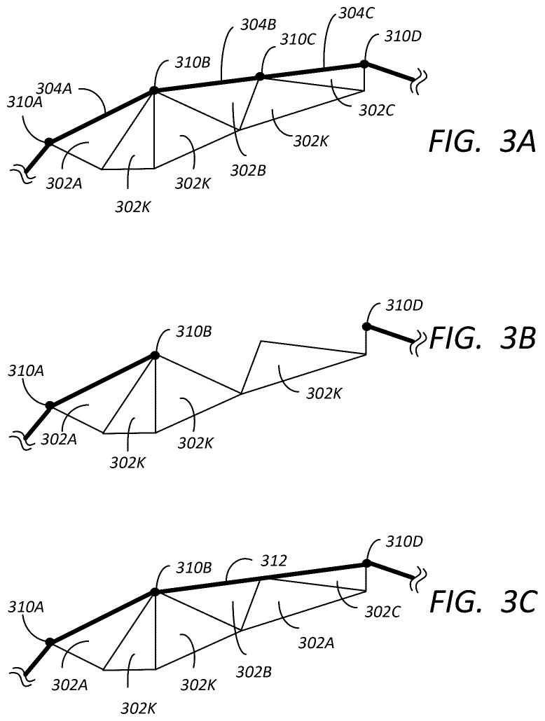

FIG. 1C is a diagram illustrating an embodiment of an exemplary technique for collating the triangle edges to produce the plurality of surface boundary edges 204A-204J from the border edges of the peripheral triangles 202A-202J. FIG. 1C is described with reference to FIGS. 3A-3C, which illustrate an exemplary embodiment of triangle edge collation. Turning first to FIG. 3A, a portion of the border of the surface 200 is depicted, and is formed by triangle edges 304A, 304B and 304C. Triangles 302K are interior triangles (those without an edge is part of the border of the surface 200) and border triangles 302A-302C). Triangle border vertices 310A-310B are vertices of triangle 302A and define triangle border edge 304A, triangle border vertices 310B and 310C are vertices of triangle 302B and define triangle border edge 304B, and triangle border vertices 310C and 310D are vertices of triangle 302C and define triangle border edge 304C.

Referring now to FIG. 1C, block 114 starts the process by considering one of the triangle border vertices, specifically and for purposes of example, triangle vertex 310B. Block 116 determines the triangle border edges that are connected to that triangle border vertex 310B. In the example illustrated in FIG. 3A, this operation identifies triangle border edges 304A and 304B. Next, block 118 determines if two and only two triangle border edges 304A and 304B are connected to the triangle border vertex 310B such that the triangle border edges 304A and 304B are colinear, but not coincident (e.g., the triangle border edges extend in opposite directions). Since the currently considered triangle border edges 304A and 304B are not colinear, block 118 routes the processing to consider the next triangle border index. In the presented example, triangle border index 310C is considered. Block 116 determines the triangle border edges that are connected to triangle border index 310C. In the example illustrated in FIG. 3A, this includes triangle border edges 304B and 304C. Again, block 118 determines if two and only two triangle border edges 304B and 304C are connected to the triangle border vertex 310C such that the triangle border edges 304B and 304C are colinear, but not coincident. Since the currently considered triangle border edges 304B and 304C are colinear and not coincident, block 118 routes processing to block 122, which discards the triangle border vertex 310C and the triangle border edges 304B and 304C that are colinear but not coincident. The result is illustrated in FIG. 3B.

Next, block 124 creates a new collated edge using the second vertices 310B and 310D of the discarded triangle border edges 304B and 304C and the discarded border vertex 310C. Finally, block 126 adjusts the second vertices 310B and 310C of the discarded edges 304B and 304C to point to the created new collated edge 312.

Returning to FIG. 1A, block 106 described presenting a dimension of the depiction of the object according to the plurality of surface boundary edges 204A-204J. In one embodiment, the dimension presented is a dimension of a dimension line.

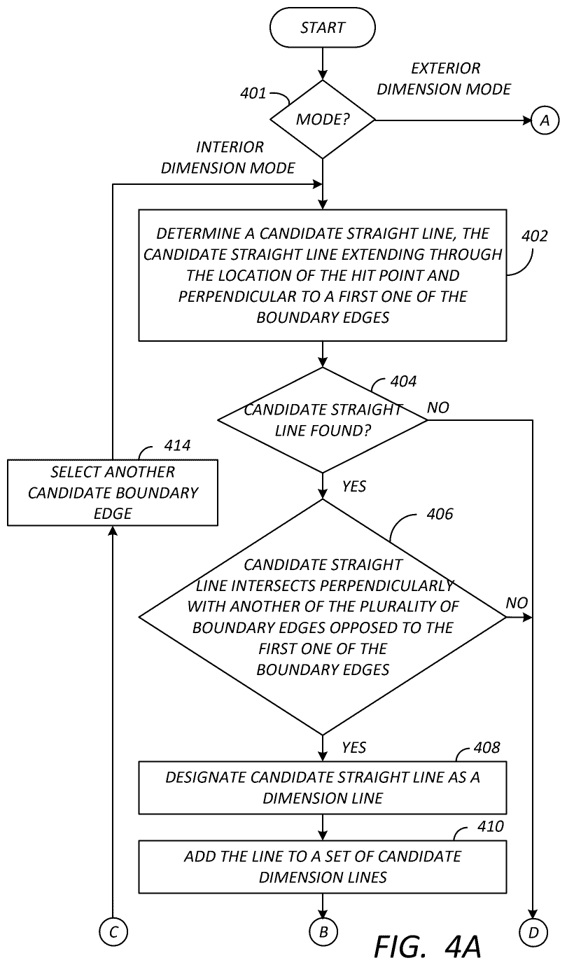

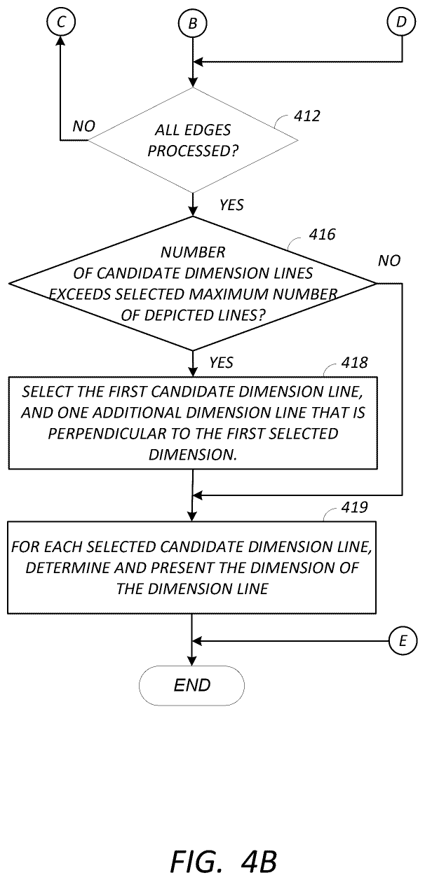

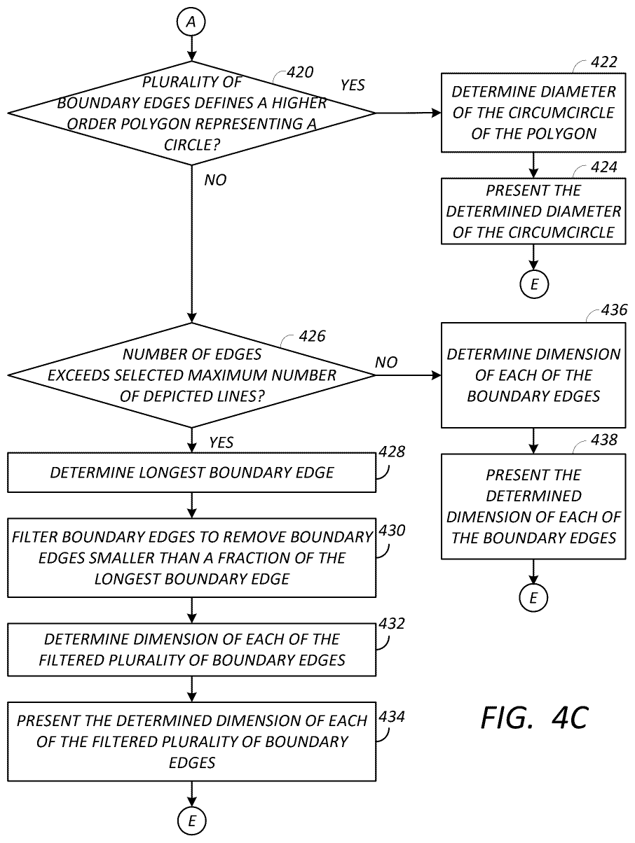

FIGS. 4A-4C are diagrams depicting exemplary operations that can be performed to present the dimension of a depicted object. FIGS. 4A and 4B depict an embodiment which determines the interior dimensions of the object, while FIG. 4C depict an embodiment that determines exterior dimensions of the object.

Turning first to FIG. 4A, the process begins by determining which mode the system is operating in, as shown by block 401. This can be determined, for example, according to a user selection. If the exterior dimension mode is selected, processing is routed to block 420 of FIG. 4C. If the selected mode is the interior dimension mode, processing is routed to block 402, which determines a candidate straight line that extends through the hit point 206 and perpendicular to a first one of the boundary edges (for example, the boundary edge formed by surface boundary edges 204A-204C). This can be accomplished, for example, by determining a candidate straight line of a random orientation, determining if the candidate straight line is perpendicular to one of the boundary edges, and if not, rotating the candidate straight line about the hit point and repeating this determination. In the embodiment illustrated in FIG. 2, candidate line 252A does not intersect any boundary edge 204A-204C perpendicularly, however, boundary line 252B (rotated from boundary line 252A by 5 degrees) intersects the boundary edge 204A-204C perpendicularly.

Returning to FIG. 4A, block 404 determines if a candidate straight line has been found. If block 404 determines that no candidate straight line was found, processing is routed to block 412, described below. If block 404 determines that a candidate straight line is found, processing is routed to block 406, which determines if the candidate straight line 252B intersects perpendicularly with another of the plurality of boundary edges opposed to the first one of the boundary edges. This can be determined by extending the candidate straight line 252B in a direction opposing the first boundary edge 204A-204C (e.g., towards second boundary edge 204F-204H). Block 408 then designates the candidate straight line as a dimension line, and block 410 adds the line to a set of candidate dimension lines. In the illustrated embodiment, the candidate straight line 252B intersects perpendicularly with second boundary edge 204F-204H, as shown by line 252C. Hence, candidate straight line 252B-252C is designated as a dimension line and is added to the set of candidate dimension lines, as shown in block 408.

Processing is then routed to block 412, which determines if all edges are processed. If all edges have not been processed, another candidate boundary line is selected, as shown in block 414, and processing is routed back to block 402.

If all edges have been processed, block 412 routes processing to block 416, which determines if the number of candidate dimension lines exceeds a selected maximum number of depicted dimension lines. If so, processing is routed to block 418, otherwise processing is routed to block 419. Block 418 selects the first candidate dimension line and one additional dimension line perpendicular to the first candidate dimension line, and routes processing to block 419. Block 419 determines and presents the dimension of each selected dimension line in the appropriate units (e.g., units of length). The dimension (length) of the dimension line is then presented to the user, preferably adjacent to the dimension line. 252B-252C.

Higher order polygons are specially considered. If the surface is a higher order polygon that has multiple candidate dimension lines, the number of dimension lines are reduced and limited to one or two. In case of a higher order regular polygon that represents a circle, the result is that a single dimension line is presented for the circle, representing the diameter of the incircle of the polygon.

Referring again to FIG. 4A, if the exterior dimension mode is selected, processing is routed to block 420 of FIG. 4C. Block 420 determines if the plurality of boundary edges together define a higher order polygon representing a circle. If so, processing is routed to blocks 422 and 424, which determine the diameter of the circumcircle of the polygon and presents the determined diameter of the circumcircle, respectively. Processing then ends.

If block 420 determines that the plurality of boundary edges does not define a higher order polygon representing a circle, processing is routed to block 426, which determines if the number of edges exceeds a maximum number of depicted lines. If not, processing is routed to blocks 436 and 438, which determine and present the dimension of each of the plurality of boundary edges. Processing then ends.

If block 426 determines that the number of edges exceeds the maximum number of depicted lines, processing is routed to blocks 428-434, which determines the longest boundary edge, filters the boundary edges to remove boundary edges smaller than a fraction of the longest boundary edge, then determines and the dimension of each of the filtered plurality of boundary edges. Processing then ends.

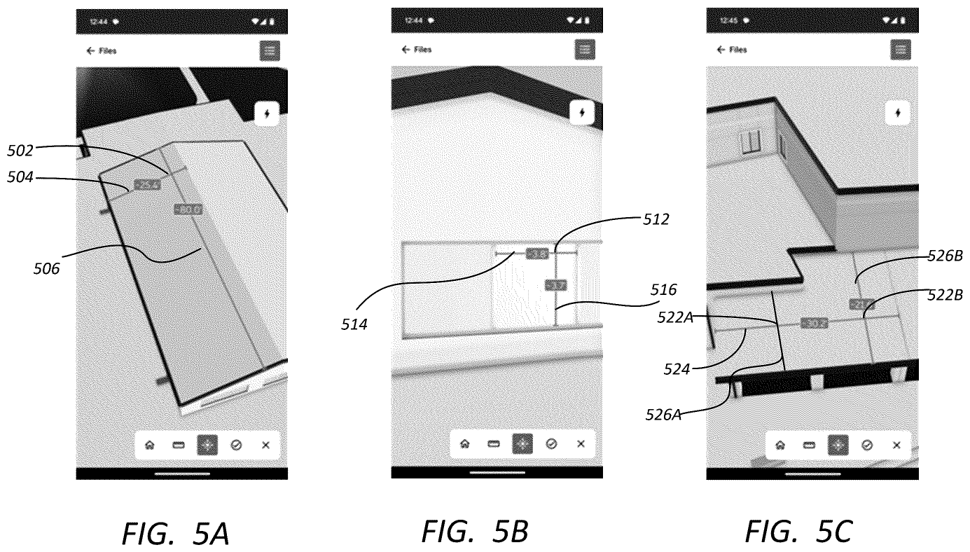

FIGS. 5A-5C are diagrams depicting embodiments of the display of dimension lines and associated dimensions. FIG. 5A depicts a roof of a structure with the hit point 502 selected within a left portion of that roof. Dimension lines 504 and 506 and associated dimensions are presented as shown. Note the foregoing discussion of determining dimension lines as perpendicular to boundary lines refers to those geometrical relationships as they are entered into the system, not necessarily as they are presented or rendered on the drawing itself. The operations described herein are independent of the orientation of the model in local and world coordinates and rely solely on the surface geometry to produce intelligent results, even if the model is rotated in the coordinate system. Hence, depending on the perspective presented, the dimension lines 502 and 504 may not appear to intersect the boundary lines perpendicularly, as is the case on FIGS. 5A-5C.

FIG. 5B discloses an embodiment similar to the embodiment presented in FIG. 5A, wherein the hit point 512 is within a window opening of the structure, resulting in dimension lines 516 and 514. FIG. 5C discloses yet another embodiment in which by judicious selection of the hit point 522A, the user may obtain dimension lines and dimensions associated with different boundary lines. If the hit point is located as shown for hit point 522A, dimension lines 524 and 526A and the associated dimensions are presented, but if the hit point is located at 522B, dimension lines 524 and 526B are presented.

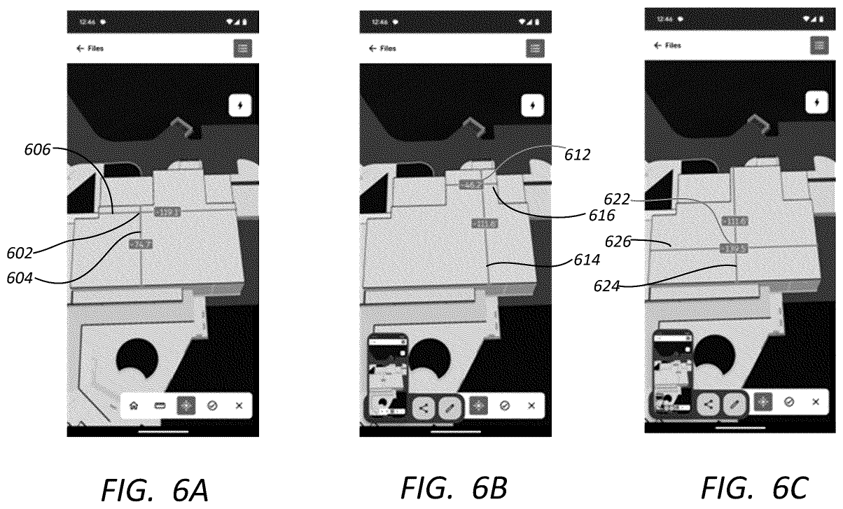

FIGS. 6A-6C are diagrams that further illustrate how judicious selection of the hit point 602 allows the user to obtain dimension lines and dimensions associated with different boundary lines. In FIG. 6A, hit point 602 results in dimension lines 606 and 604 which represent the dimensions of interior portions of the object. In FIG. 6B, hit point 612 results in dimension lines 614 and 616, which represent the height of the object and the width of the upper rectangle, respectively. Further, in FIG. 6C, hit point 622 results in dimension lines 624 and 626, which represent the maximum height and width of the object, respectively.

With respect to curved objects, the illustrated quick dimension feature uses crease angles to select the connected surface triangles, and finds primary dimensions for objects like pipes, columns, and other cylindrical objects. A crease angle is a threshold angle between two faces of a surface, wherein the faces are used to approximate a curved surface. For example, consider a curved surface having a radius R. The surface can be approximated by a plurality of faces that roughly follow the same geometry as the curved surface, thus giving the appearance of a surface with one or more creases. The crease angle is the angle between a normal vector of one face and the normal vector of an adjacent face. Once a surface is collected using adjacent triangles whose normals are within the crease angle tolerance, surface edges can be determined using the same embodiments 1A, 1B and 1C. Following that, dimensions are produced following the same embodiments as 4A.

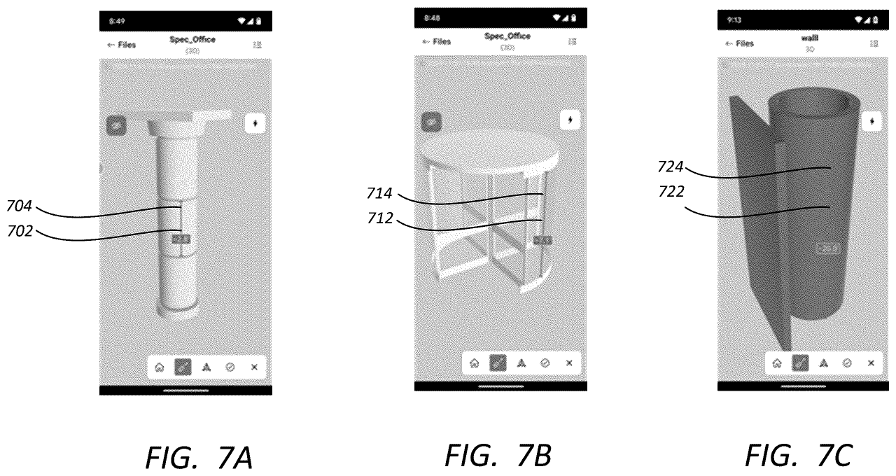

FIGS. 7A-7C illustrate the depictions of dimension lines 704, 714, and 724 and associated dimensions used on curved surfaces, presented after selection of hit points 702, 712, and 722, respectively.

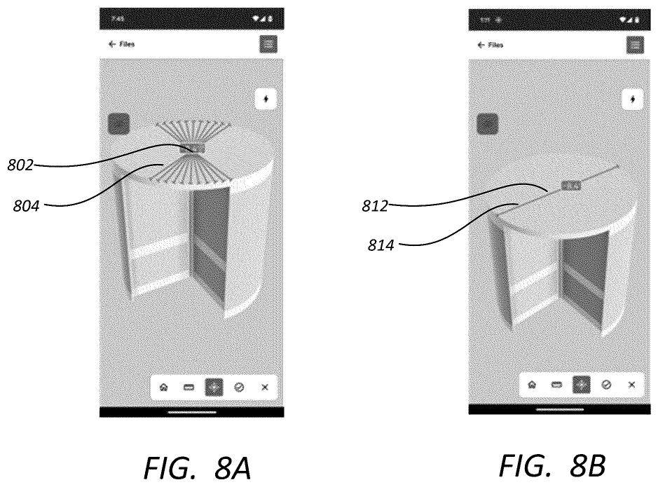

FIGS. 8A and 8B illustrate a particular use case wherein the object is circular and hit point 802 results in dimension lines 804. In such cases, a large number of dimension 804 lines may be computed and displayed, as shown in FIG. 8A. Since the object is circular (and no additional information is presented to the user by depicting a plurality of diametrical lines), the system recognizes that the dimension of that object can be represented by a single dimension, and the system presents only a single dimension line and dimension 814, after selection of hit point 812 as illustrated in FIG. 8B.

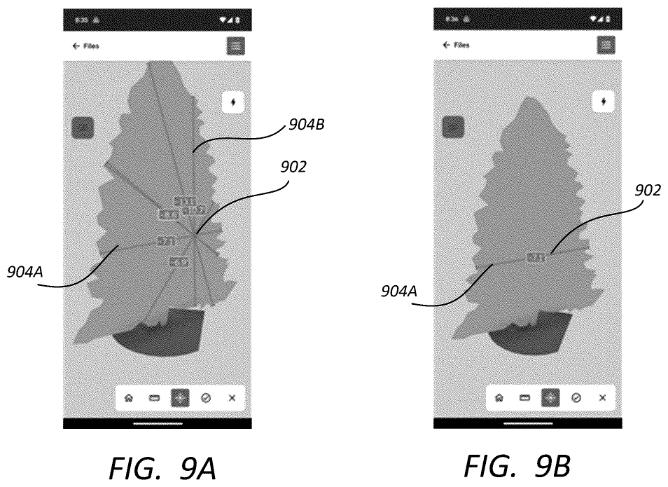

FIGS. 9A and 9B illustrate a use case where the depicted object is a high order polygon with several edges. In such case, a tap at the hit point 902 can result in multiple measure lines (for example, 904A and 904B) through the hit point 902. It is not useful or intelligible to show so many dimensions through a point at the same time, so one embodiment of the system and method limits the number of such dimension lines and associated dimensions presented with respect to a hit point 902 to a number that may be user-defined, as implemented by block 416 of FIG. 4B. In the embodiment illustrated in FIG. 9B, the number of dimensions is limited to one, but other values for the maximum number of dimension lines and dimensions may be specified.

Returning to FIG. 4A, if block 401 determines if the exterior dimension mode is selected, the system is in the edge dimension mode, and a tap on a surface will automatically compute dimensions of all border edges of that surface, thus producing a single, clearly marked circumcircle diameter measure. If the exterior dimension mode is selected, processing is routed to block 420, which determines if the plurality of boundary edges defines a higher order polygon representing a circle. What number of boundary edges defines a higher order polygon may be selected by the user. If the plurality of boundary edges defines a higher order polygon representing a circle, processing is routed to blocks 422-424 which computes and displays the diameter of the circumcircle of the polygon. If not, it is routed to 426, which will determine whether further filtering is necessary based on the number of edges. If it is not necessary, it routes to 436-438 which determine the dimension of each of the plurality of boundary edges, and provide them to the user for display. Otherwise it is routed to 428-434 which will filter the edges and display the dimensions of the remaining to the user.

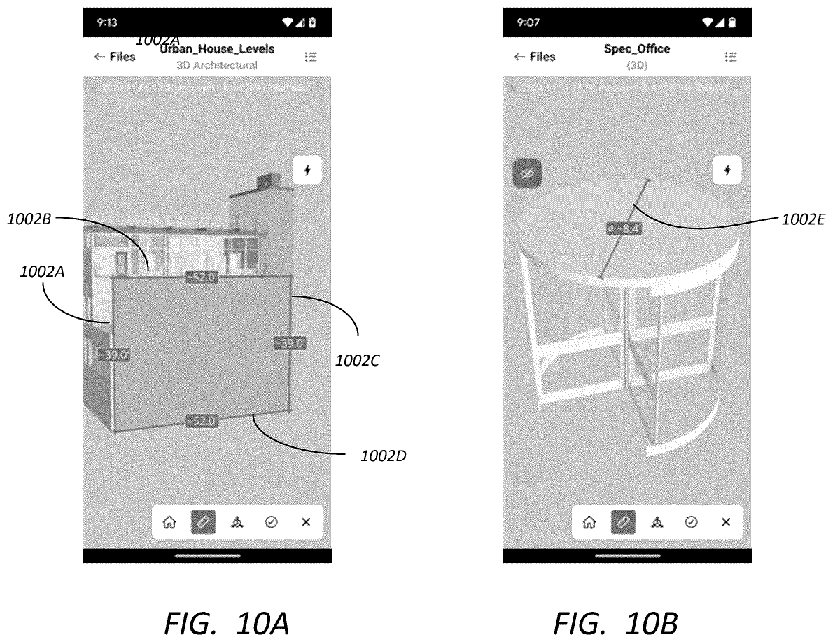

FIG. 10A is a diagram illustrating an exemplary result of using the exterior dimension mode to determine the dimensions of a wall, using boundary edges 1002A-1002D. If the plurality of boundary edges defines a higher order polygon, processing is routed to block 426, which determines if the plurality of boundary edges represents a circle. In one embodiment, this is determined that the plurality of boundary edges represents a circle if all of the plurality of boundary edges are the same length and each triangle border vertex is equidistant from a centroid of all of the triangle border vertices.

If the plurality of boundary edges represents a circle, processing is routed to blocks 422 and 424, which determine and present the diameter of the circle. Determining the line representing the diameter and the diameter itself can be accomplished, for example, using the techniques described with respect to FIGS. 4A and 4B.

FIG. 10B is a diagram illustrating one embodiment of how a line showing the diameter of the circle and the length of that diameter may be presented.

In case of a surface with several edges, especially ones with curved edges or partial holes in them, a tap can result in hundreds of small boundary edges. It is less useful or intelligible to show such dimensions, so one embodiment limits the edges shown to those whose lengths are a certain percentage of the longest edge. This is illustrated in blocks 428-434 of FIG. 4C.

If block 426 determines that the plurality of border edges defines a higher order polygon that does not represent a circle, processing is routed to block 428, which determines the longest boundary edge. The boundary edges are then filtered to remove boundary edges smaller than a fraction of the longest boundary edge, as shown in block 430. The fraction used for filtering may be user selected. Then in block 432, the dimension of each of the remaining (after filtering) boundary edges is determined, and in block 434, the edges and dimensions of the edges are presented.

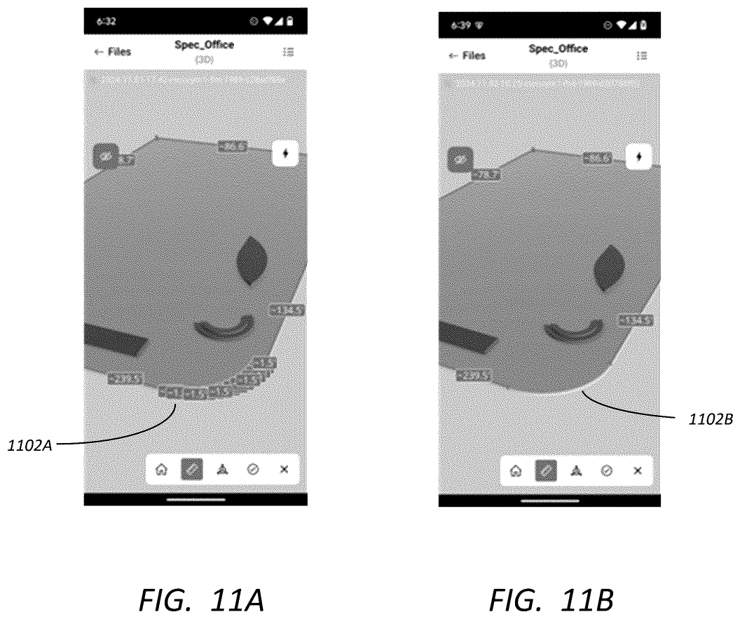

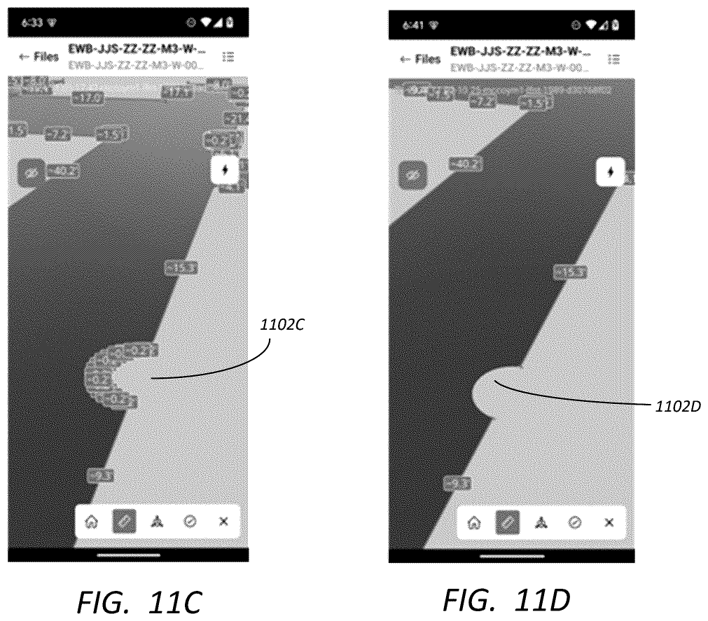

FIGS. 11A-11D are diagrams illustrating one embodiment of the result of edge-dimensioning higher order polygons as described in FIG. 4C. In this embodiment, the fraction used for filtering is 1% ( 1/100), and hence any boundary edges less than 1/100^{th} of the longest boundary edge are not reproduced. Note that before filtering, the object includes a curved surface represented by a large number of boundary edges 1102A and 1102C. After the filtering process of block 434, the curved section 1102B and 1102D represented by the boundary edges 1102A and 1102C in FIG. 11A are not reproduced.

### Hardware Environment

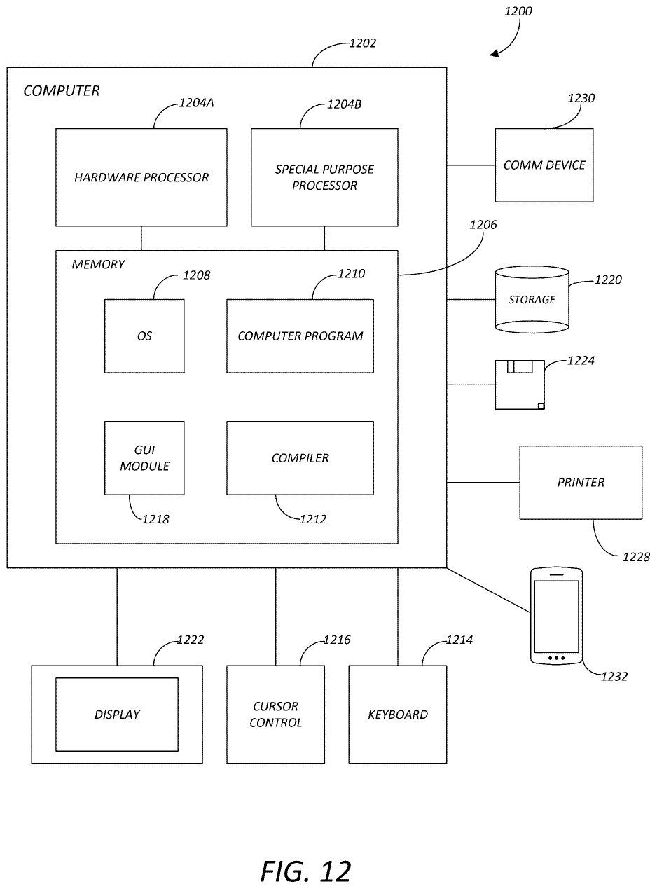

FIG. 12 is an exemplary hardware and software environment 1200 (referred to as a computer-implemented system and/or computer-implemented method) used to implement one or more embodiments of the invention. The hardware and software environment includes a computer 1202 and may include peripherals. Computer 1202 may be a user/client computer, server computer, or may be a database computer. The computer 1202 comprises a hardware processor 1204A and/or a special purpose hardware processor 1204B (hereinafter alternatively collectively referred to as processor 1204) and a memory 1206, such as random access memory (RAM). The computer 1202 may be coupled to, and/or integrated with, other devices, including input/output (I/O) devices such as a keyboard 1214, a cursor control device 1216 (e.g., a mouse, a pointing device, pen and tablet, touch screen, multi-touch device, etc.) and a printer 1228. In one or more embodiments, computer 1202 may be coupled to, or may comprise, a portable or media viewing/listening device 1232 (e.g., an MP3 player, IPOD, NOOK, portable digital video player, cellular device, personal digital assistant, etc.). In yet another embodiment, the computer 1202 may comprise a multi-touch device, mobile phone, gaming system, internet enabled television, television set top box, or other internet enabled device executing on various platforms and operating systems.

In one embodiment, the computer 1202 operates by the hardware processor 1204A performing instructions defined by the computer program 1210 (e.g., a computer-aided design [CAD] application) under control of an operating system 1208. The computer program 1210 and/or the operating system 1208 may be stored in the memory 1206 and may interface with the user and/or other devices to accept input and commands and, based on such input and commands and the instructions defined by the computer program 1210 and operating system 1208, to provide output and results.

Output/results may be presented on the display 1222 or provided to another device for presentation or further processing or action. In one embodiment, the display 1222 comprises a liquid crystal display (LCD) having a plurality of separately addressable liquid crystals. Alternatively, the display 1222 may comprise a light emitting diode (LED) display having clusters of red, green and blue diodes driven together to form full-color pixels. Each liquid crystal or pixel of the display 1222 changes to an opaque or translucent state to form a part of the image on the display in response to the data or information generated by the processor 1204 from the application of the instructions of the computer program 1210 and/or operating system 1208 to the input and commands. The image may be provided through a graphical user interface (GUI) module 1218. Although the GUI module 1218 is depicted as a separate module, the instructions performing the GUI functions can be resident or distributed in the operating system 1208, the computer program 1210, or implemented with special purpose memory and processors.

In one or more embodiments, the display 1222 is integrated with/into the computer 1202 and comprises a multi-touch device having a touch sensing surface (e.g., track pod, touch screen, smartwatch, smartglasses, smartphones, laptop or non-laptop personal mobile computing devices) with the ability to recognize the presence of two or more points of contact with the surface. Examples of multi-touch devices include mobile devices (e.g., IPHONE, ANDROID devices, WINDOWS phones, GOOGLE PIXEL devices, NEXUS S, etc.), tablet computers (e.g., IPAD, HP TOUCHPAD, SURFACE Devices, etc.), portable/handheld game/music/video player/console devices (e.g., IPOD TOUCH, MP3 players, NINTENDO SWITCH, PLAYSTATION PORTABLE, etc.), touch tables, and walls (e.g., where an image is projected through acrylic and/or glass, and the image is then backlit with LEDs).

Some or all of the operations performed by the computer 1202 according to the computer program 1210 instructions may be implemented in a special purpose processor 1204B. In this embodiment, some or all of the computer program 1210 instructions may be implemented via firmware instructions stored in a read only memory (ROM), a programmable read only memory (PROM) or flash memory within the special purpose processor 1204B or in memory 1206. The special purpose processor 1204B may also be hardwired through circuit design to perform some or all of the operations to implement the present invention. Further, the special purpose processor 1204B may be a hybrid processor, which includes dedicated circuitry for performing a subset of functions, and other circuits for performing more general functions such as responding to computer program 1210 instructions. In one embodiment, the special purpose processor 1204B is an application specific integrated circuit (ASIC).

The computer 1202 may also implement a compiler 1212 that allows an application or computer program 1210 written in a programming language such as C, C++, Assembly, SQL, PYTHON, PROLOG, MATLAB, RUBY, RAILS, HASKELL, or other language to be translated into processor 1204 readable code. Alternatively, the compiler 1212 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 1210 accesses and manipulates data accepted from I/O devices and stored in the memory 1206 of the computer 1202 using the relationships and logic that were generated using the compiler 1212.

The computer 1202 also optionally comprises an external communication device such as a modem, satellite link, Ethernet card, or other device for accepting input from, and providing output to, other computers 1202.

In one embodiment, instructions implementing the operating system 1208, the computer program 1210, and the compiler 1212 are tangibly embodied in a non-transitory computer-readable medium, e.g., data storage device 1220, which could include one or more fixed or removable data storage devices, such as a zip drive, floppy disc drive 1224, hard drive, CD-ROM drive, tape drive, etc. Further, the operating system 1208 and the computer program 1210 are comprised of computer program 1210 instructions which, when accessed, read and executed by the computer 1202, cause the computer 1202 to perform the steps necessary to implement and/or use the present invention or to load the program of instructions into a memory 1206, thus creating a special purpose data structure causing the computer 1202 to operate as a specially programmed computer executing the method steps described herein. Computer program 1210 and/or operating instructions may also be tangibly embodied in memory 1206 and/or data communications devices 1230, thereby making a computer program product or article of manufacture according to the invention. As such, the terms “article of manufacture,” “program storage device,” and “computer program product,” as used herein, are intended to encompass a computer program accessible from any computer readable device or media.

Of course, those skilled in the art will recognize that any combination of the above components, or any number of different components, peripherals, and other devices, may be used with the computer 1202.

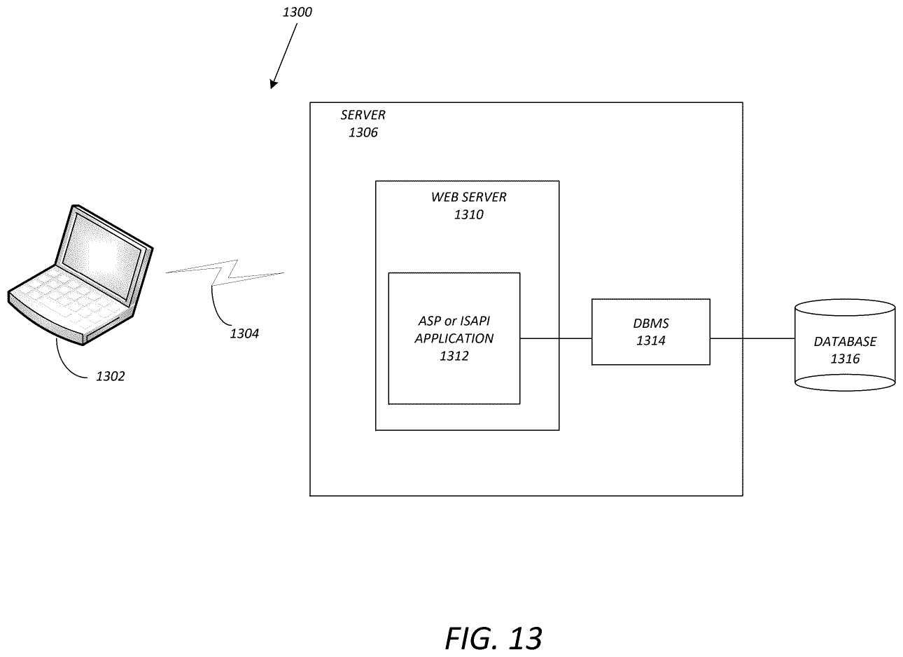

FIG. 13 schematically illustrates a typical distributed/cloud-based computer system 1300 using a network 1304 to connect client computers 1302 to server computers 1306. A typical combination of resources may include a network 1304 comprising the Internet, LANs (local area networks), WANs (wide area networks), SNA (systems network architecture) networks, or the like, clients 1302 that are personal computers or workstations (as set forth in FIG. 12), and servers 1306 that are personal computers, workstations, minicomputers, or mainframes (as set forth in FIG. 12). However, it may be noted that different networks such as a cellular network (e.g., GSM [global system for mobile communications] or otherwise), a satellite based network, or any other type of network may be used to connect clients 1302 and servers 1306 in accordance with embodiments of the invention.

A network 1304 such as the Internet connects clients 1302 to server computers 1306. Network 1304 may utilize ethernet, coaxial cable, wireless communications, radio frequency (RF), etc. to connect and provide the communication between clients 1302 and servers 1306. Further, in a cloud-based computing system, resources (e.g., storage, processors, applications, memory, infrastructure, etc.) in clients 1302 and server computers 1306 may be shared by clients 1302, server computers 1306, and users across one or more networks. Resources may be shared by multiple users and can be dynamically reallocated per demand. In this regard, cloud computing may be referred to as a model for enabling access to a shared pool of configurable computing resources.

Clients 1302 may execute a client application or web browser and communicate with server computers 1306 executing web servers 1310. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 1302 may be downloaded from server computer 1306 to client computers 1302 and installed as a plug-in or ACTIVEX control of a web browser. Accordingly, clients 1302 may utilize ACTIVEX components/component object model (COM) or distributed COM (DCOM) components to provide a user interface on a display of client 1302. The web server 1310 is typically a program such as MICROSOFT'S INTERNET INFORMATION SERVER.

Web server 1310 may host an Active Server Page (ASP) or Internet Server Application Programming Interface (ISAPI) application 1312, which may be executing scripts. The scripts invoke objects that execute business logic (referred to as business objects). The business objects then manipulate data in database 1316 through a database management system (DBMS) 1314. Alternatively, database 1316 may be part of, or connected directly to, client 1302 instead of communicating/obtaining the information from database 1316 across network 1304. When a developer encapsulates the business functionality into objects, the system may be referred to as a component object model (COM) system. Accordingly, the scripts executing on web server 1310 (and/or application 1312) invoke COM objects that implement the business logic. Further, server 1306 may utilize MICROSOFT'S TRANSACTION SERVER (MTS) to access required data stored in database 1316 via an interface such as ADO (Active Data Objects), OLE DB (Object Linking and Embedding DataBase), or ODBC (Open DataBase Connectivity).

Generally, these components 1300-1316 all comprise logic and/or data that is embodied in/or retrievable from device, medium, signal, or carrier, e.g., a data storage device, a data communications device, a remote computer, or device coupled to the computer via a network or via another data communications device, etc. Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 1302 and 1306 may be interchangeable and may further include thin client devices with limited or full processing capabilities, portable devices such as cell phones, notebook computers, pocket computers, multi-touch devices, and/or any other devices with suitable processing, communication, and input/output capability.

Of course, those skilled in the art will recognize that any combination of the above components, or any number of different components, peripherals, and other devices, may be used with computers 1302 and 1306. Embodiments of the invention are implemented as a software/CAD application on a client 1302 or server computer 1306. Further, as described above, the client 1302 or server computer 1306 may comprise a thin client device or a portable device that has a multi-touch-based display.

Those skilled in the art will recognize many modifications may be made to this configuration without departing from the scope of the present disclosure. For example, those skilled in the art will recognize that any combination of the above components, or any number of different components, peripherals, and other devices, may be used.

### Conclusion

This concludes the description of the preferred embodiments of the present disclosure.

The foregoing description of the preferred embodiment has been presented for the purposes of illustration and description. It is not intended to be exhaustive or to limit the disclosure to the precise form disclosed. Many modifications and variations are possible in light of the above teaching. It is intended that the scope of rights be limited not by this detailed description, but rather by the claims appended hereto.

What is claimed is:

1. A method of automatically presenting a dimension of a depiction of an object, comprising:
accepting a hit point on the depiction of the object;
automatically performing:
determining a surface of the depicted object, the surface having a plurality of boundary edges, wherein the hit point is within the plurality of boundary edges of the surface, comprising:
collecting a plurality of connected triangles and edges that form the surface;
for each connected triangle, determining the triangle edges that form the border of the surface, and the triangle border vertices;
collating the triangle edges to produce the plurality of surface boundary edges from the triangle border edges; and
presenting the dimension according to the plurality of surface boundary edges.

2. The method of claim 1, wherein collating the triangle edges to produce the plurality of surface boundary edges from the triangle border edges comprises:
for each triangle border vertex:
determining the triangle border edges that are connected to that triangle border vertex;
determining that there are two and only two triangle border edges connected to the triangle border vertex such that the triangle border edges are colinear but not coincident;
discarding the triangle border vertex and the triangle border edges that are colinear but not coincident;
creating a new collated edge using second vertices of the discarded triangle border edges; and
adjusting the second vertices of the discarded edges to point to the created new collated edge.

3. The method of claim 2, wherein presenting the dimension according to the plurality of boundary edges comprises:
determining a candidate straight line, the candidate straight line extending through the location of the hit point and perpendicular to a first one of the boundary edges;
determining that the candidate straight line intersects perpendicularly with another of the plurality of boundary edges opposed to the first one of the boundary edges;
based on the determining that the candidate straight line intersects perpendicularly with the another of the plurality of boundary edges opposed to the first one of the boundary edges:
designating the candidate straight line as a dimension line;
determining the dimension of the dimension line; and
presenting the dimension of the dimension line.

4. The method of claim 3, further comprising:
determining that there are duplicate candidate straight lines; and
based on the determining that there are duplicate candidate straight lines:
eliminating the duplicate candidate straight lines.

5. The method of claim 3, further comprising:
(a) determining a second candidate straight line, the second candidate straight line extending through the location of the hit point and perpendicular to a second one of the boundary edges;
(b) determining that the second candidate straight line intersects perpendicularly with still another of the plurality of boundary edges opposed to the first one of the boundary edges;
(c) based on the determining that the second candidate straight line intersects perpendicularly with still another of the plurality of boundary edges opposed to the first one of the boundary edges:
(d) designating the second candidate straight line as a second dimension line;
(e) determining a dimension of the second dimension line; and
(f) presenting the dimension of the second dimension line.

6. The method of claim 5, further comprising:
repeating steps (a)-(f) to determine further dimension lines, determine a dimension for the further dimension lines, and present the dimensions of the further dimension lines.

7. The method of claim 6, wherein:
steps (a)-(f) are repeated to designate a limited number of further dimension lines.

8. The method of claim 5, wherein the limited number of further dimension lines is user-defined.

9. The method of claim 1, wherein the object comprises a curved surface boundary represented according to a crease angle.

10. The method of claim 1, wherein presenting the dimension according to the plurality of boundary edges comprises:
determining a dimension of each of the plurality of boundary edges; and
presenting the determined dimension of each of the plurality of boundary edges.

11. The method of claim 10, wherein collating the triangle edges to produce the plurality of polygon boundary edges from the triangle border edges comprises:
for each triangle border vertex:
determining the triangle border edges that are connected to that triangle border vertex;
determining that there are two and only two triangle border edges connected to the triangle border vertex such that the triangle border edges are colinear but not coincident;
discarding the triangle border vertex and the triangle border edges that are colinear but not coincident;
creating a new collated edge using second vertices of the discarded triangle border edges and the discarded triangle border vertex; and
adjusting the second vertices of the discarded edges to point to the created new collated edge.

12. The method of claim 11, wherein:
the method further comprises:
determining that the plurality of boundary edges defines a high order polygon representing a circle; and
based on the determining that the plurality of boundary edges defines a high order polygon representing a circle, determining a diameter of the circle;
presenting the determined dimension of each of the plurality of boundary edges comprises:
presenting the determined diameter of the circle.

13. The method of claim 12, wherein:
determining that the plurality of boundary edges defines a high order polygon representing a circle comprises:
determining that all of the plurality of boundary edges are the same length and each triangle border vertex is equidistant from a centroid of all of the triangle border vertices.

14. The method of claim 11, wherein:
the method further comprises:
determining that the plurality of boundary edges defines a high order polygon not representing a circle;
based on the determining that the plurality of boundary edges defines a high order polygon not representing a circle:
determining the longest boundary edge;
filter the boundary edges to remove boundary edges smaller than a fraction of the longest boundary edge;
determining a dimension of each of the plurality of boundary edges comprises:
determining a dimension of each of the filtered plurality of boundary edges
presenting the determined dimension of each of the plurality of boundary edges comprises:
presenting the determined dimension of each of the filtered plurality of boundary edges.

15. An apparatus for automatically presenting a dimension of a depiction of an object, comprising:
a processor;
a memory, communicatively coupled to the processor, the memory storing processor instructions including processor instructions for:
accepting a hit point on the depiction of the object;
automatically performing:
determining a surface of the depicted object, the surface having a plurality of boundary edges, wherein the hit point is within the plurality of boundary edges of the surface, comprising:
collecting a plurality of connected triangles and edges that form the surface; wherein the connectivity of the triangles is determined using a crease angle;
for each connected triangle, determining the triangle edges that form the border of the surface, and the triangle border vertices;
collating the triangle edges to produce the plurality of surface boundary edges from the triangle border edges; and
presenting the dimension according to the plurality of surface boundary edges.

16. The apparatus of claim 15, wherein the processor instructions for collating the triangle edges to produce the plurality of surface boundary edges from the triangle border edges comprises processor instructions for:
for each triangle border vertex:
determining the triangle border edges that are connected to that triangle border vertex;
determining that there are two and only two triangle border edges connected to the triangle border vertex such that the triangle border edges are colinear but not coincident;
discarding the triangle border vertex and the triangle border edges that are colinear but not coincident;
creating a new collated edge using second vertices of the discarded triangle border edges and the discarded triangle border vertex; and
adjusting the second vertices of the discarded edges to point to the created new collated edge.

17. The apparatus of claim 16, wherein the processor instructions for presenting the dimension according to the plurality of boundary edges comprise processor instructions for:
determining a candidate straight line, the candidate straight line extending through the location of the hit point and perpendicular to a first one of the boundary edges;
determining that the candidate straight line intersects perpendicularly with another of the plurality of boundary edges opposed to the first one of the boundary edges;
based on the determining that the candidate straight line intersects perpendicularly with the another of the plurality of boundary edges opposed to the first one of the boundary edges:
designating the candidate straight line as a dimension line;
determining the dimension of the dimension line; and
presenting the dimension of the dimension line.

18. The apparatus of claim 15, wherein the processor instructions for presenting the dimension according to the plurality of boundary edges comprise processor instructions for:
determining a dimension of each of the plurality of boundary edges; and
presenting the determined dimension of each of the plurality of boundary edges.

19. The apparatus of claim 18, wherein the processor instructions for collating the triangle edges to produce the plurality of surface boundary edges from the triangle border edges comprise processor instructions for:
for each triangle border vertex:
determining the triangle border edges that are connected to that triangle border vertex;
determining that there are two and only two triangle border edges connected to the triangle border vertex such that the triangle border edges are colinear but not coincident;
discarding the triangle border vertex and the triangle border edges that are colinear but not coincident;
creating a new collated edge using second vertices of the discarded triangle border edges and the discarded triangle border vertex; and
adjusting the second vertices of the discarded edges to point to the created new collated edge.

20. The apparatus of claim 19, wherein:
the method further comprises:
determining that the plurality of boundary edges defines a high order polygon representing a circle; and
based on the determining that the plurality of boundary edges defines a high order polygon representing a circle, determining a diameter of the circle;
presenting the determined dimension of each of the plurality of boundary edges comprises:
presenting the determined diameter of the circle.
